(19) United States
(12) Patent Application Publication
(10) Pub. No.: US 2024/0260223 A1
(43) Pub. Date: Aug. 1, 2024

(54) MULTI-SHELF MOUNTING SOLUTION

(71) Applicant: Dell Products L.P., Round Rock, TX (US)

(72) Inventors: Richard Andrew CRISP, Austin, TX (US); Kevin Warren MUNDT, Austin, TX (US); Brad COLLINS, Austin, TX (US); Peter KALTENBACH, Austin, TX (US)

(73) Assignee: Dell Products L.P., Round Rock, TX (US)

(21) Appl. No.: 18/162,088

(22) Filed: Jan. 31, 2023

(51) Int. Cl. H05K 7/18; H05K 7/14

(52) U.S. Cl. CPC H05K 7/183; H05K 7/1489

(57) ABSTRACT

A server shelf may include a left rail panel coupleable to a left side of a server rack, the left rail panel including left rack rails; and a right rail panel coupleable to a right side of the server rack, the right rail panel including right rack rails. Each left rack rail may include a horizontal upper protrusion and an angled lower protrusion configured to receive a left server rail therebetween, and each right rack rail may include a horizontal upper protrusion and an angled lower protrusion configured to receive a right server rail therebetween. The left server rail and the right server rail may be coupleable to a server of a first size and insertable into the server shelf, and the left server rail and the right server rail may be coupleable to a server of a second, different size and insertable into the server shelf.

### TECHNICAL FIELD

The present disclosure relates in general to information handling systems, and more particularly to techniques for mounting information handling systems in a rack.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Currently, when an information handling system such as a server is installed into a rack, it typically uses a set of either static or sliding rails to mount. Sliding rails are often used for servers that need to be serviced in situ. They generally contain ball bearings and allow for the server to be translated along its entire depth while remaining coupled to the rack.

Static rails are often used in systems that are cabled in a way that prevents a cable management arm (CMA) and/or sliding rail from being used. This is common in large-scale deployments such as hyperscale environments, in which servers are typically not serviced in situ.

Embodiments of the present disclosure allow a simplified static rail system in which a “multi-shelf” can be used to mount multiple servers, reducing the number of rails needed and speeding up deployment. However, one difficulty is that different sizes of servers may have different requirements. For example, among servers that are dimensioned for standard EIA-310 rack units, 1U servers have different mounting requirements than 2U servers. The mounting features may be different, and chassis designs typically do not allow a 2U server to fit where 1U static mount features are installed. Embodiments of this disclosure provide a solution to these and other mounting issues, allowing customers to install a mix of server sizes in a multi-shelf solution.

It should be noted that the discussion of a technique in the Background section of this disclosure does not constitute an admission of prior-art status. No such admissions are made herein, unless clearly and unambiguously identified as such.

### SUMMARY

In accordance with the teachings of the present disclosure, the disadvantages and problems associated with mounting information handling systems may be reduced or eliminated.

In accordance with embodiments of the present disclosure, server shelf may include a left rail panel coupleable to a left side of a server rack, the left rail panel including left rack rails; and a right rail panel coupleable to a right side of the server rack, the right rail panel including right rack rails. Each left rack rail may include a horizontal upper protrusion and an angled lower protrusion configured to receive a left server rail therebetween, and each right rack rail may include a horizontal upper protrusion and an angled lower protrusion configured to receive a right server rail therebetween. The left server rail and the right server rail may be coupleable to a server of a first size and insertable into the server shelf, and the left server rail and the right server rail may be coupleable to a server of a second, different size and insertable into the server shelf. In accordance with these and other embodiments of the present disclosure, a method may include forming a left rail panel that is coupleable to a left side of a server rack, the left rail panel including a plurality of left rack rails; and forming a right rail panel that is coupleable to a right side of the server rack, the right rail panel including a plurality of right rack rails; wherein each left rack rail includes a horizontal upper protrusion and an angled lower protrusion configured to receive a left server rail therebetween, and each right rack rail includes a horizontal upper protrusion and an angled lower protrusion configured to receive a right server rail therebetween; wherein the left server rail and the right server rail are coupleable to a server of a first size and insertable into the server shelf; and wherein the left server rail and the right server rail are coupleable to a server of a second, different size and insertable into the server shelf.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIGS. 2, 2A, and 2B illustrate a server rack in which different size servers are unable to fit in a single set of rails;

FIGS. 3A and 3B illustrate slidable rack panels in a multi-shelf system, in accordance with embodiments of the present disclosure;

FIGS. 4A and 4B illustrate close-up views of different size servers that are able to fit in a single set of rails, in accordance with embodiments of the present disclosure;

FIG. 5 illustrates a side view of different server rails installed on servers, in accordance with embodiments of the present disclosure; and

FIG. 6 illustrates a side view of different server and rack rails installed in a rack, in accordance with embodiments of the present disclosure.

### DETAILED DESCRIPTION

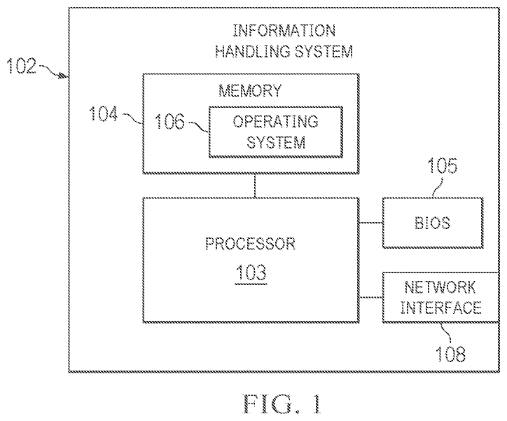

Preferred embodiments and their advantages are best understood by reference to FIGS. 1 through 6, wherein like numbers are used to indicate like and corresponding parts.

For the purposes of this disclosure, the term “information handling system” may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”) or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

For purposes of this disclosure, when two or more elements are referred to as “coupled” to one another, such term indicates that such two or more elements are in electronic communication or mechanical communication, as applicable, whether connected directly or indirectly, with or without intervening elements.

When two or more elements are referred to as “coupleable” to one another, such term indicates that they are capable of being coupled together.

For the purposes of this disclosure, the term “computer-readable medium” (e.g., transitory or non-transitory computer-readable medium) may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; communications media such as wires, optical fibers, microwaves, radio waves, and other electromagnetic and/or optical carriers; and/or any combination of the foregoing.

For the purposes of this disclosure, the term “information handling resource” may broadly refer to any component system, device, or apparatus of an information handling system, including without limitation processors, service processors, basic input/output systems, buses, memories, I/O devices and/or interfaces, storage resources, network interfaces, motherboards, and/or any other components and/or elements of an information handling system.

FIG. 1 illustrates a block diagram of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data (which may generally be referred to as “physical storage resources”). As shown in FIG. 1, information handling system 102 may comprise a processor 103, a memory 104 communicatively coupled to processor 103, a BIOS 105 (e.g., a UEFI BIOS) communicatively coupled to processor 103, a network interface 108 communicatively coupled to processor 103. In addition to the elements explicitly shown and described, information handling system 102 may include one or more other information handling resources.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may include any system, device, or apparatus configured to retain program instructions and/or data for a period of time (e.g., computer-readable media). Memory 104 may include RAM, EEPROM, a PCMCIA card, flash memory, magnetic storage, opto-magnetic storage, or any suitable selection and/or array of volatile and/or non-volatile memory that retains data after power to information handling system 102 is turned off.

As shown in FIG. 1, memory 104 may have stored thereon an operating system 106. Operating system 106 may comprise any program of executable instructions (or aggregation of programs of executable instructions) configured to manage and/or control the allocation and usage of hardware resources such as memory, processor time, disk space, and input and output devices, and provide an interface between such hardware resources and application programs hosted by operating system 106. In addition, operating system 106 may include all or a portion of a network stack for network communication via a network interface (e.g., network interface 108 for communication over a data network). Although operating system 106 is shown in FIG. 1 as stored in memory 104, in some embodiments operating system 106 may be stored in storage media accessible to processor 103, and active portions of operating system 106 may be transferred from such storage media to memory 104 for execution by processor 103.

Network interface 108 may comprise one or more suitable systems, apparatuses, or devices operable to serve as an interface between information handling system 102 and one or more other information handling systems via an in-band network. Network interface 108 may enable information handling system 102 to communicate using any suitable transmission protocol and/or standard. In these and other embodiments, network interface 108 may comprise a network interface card, or “NIC.” In these and other embodiments, network interface 108 may be enabled as a local area network (LAN)-on-motherboard (LOM) card.

As discussed above, embodiments of this disclosure provide a multi-shelf allowing for multiple information handling systems 102 having different dimensions to be mounted therein.

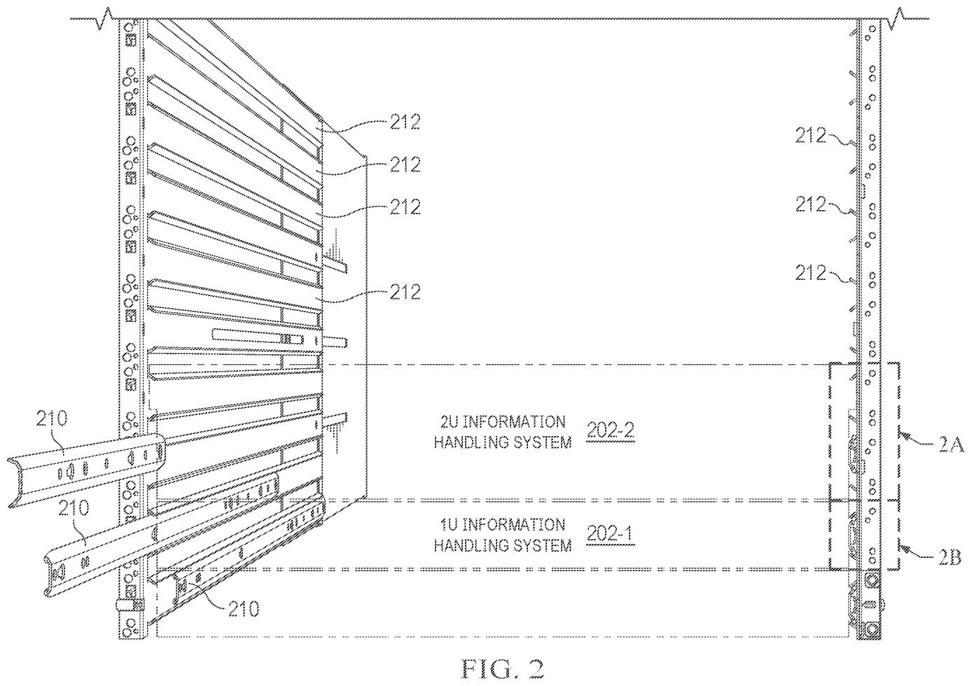

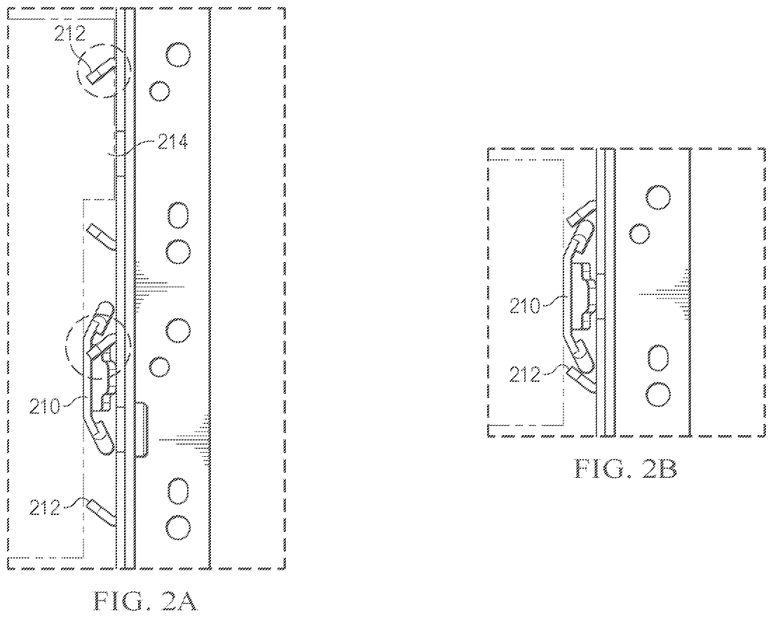

FIGS. 2, 2A, and 2B show an embodiment of a server rack and rail system designed to accommodate 1U information handling systems 202-1. Server rails 210 are attached (e.g., screwed) to the sides of 1U information handling system 202-1 and fit securely with rack rails 212 when 1U information handling system 202-1 is installed. This is shown in FIGS. 2 and 2B.

However, when an attempt is made to install a 2U information handling system 202-2 into this system, multiple problems arise, as shown in FIGS. 2 and 2A. In particular, when server rails 210 are attached (e.g., screwed) to 2U information handling system 202-2, the mounting locations on system 202-2 cause server rails 210 to be shifted upward, preventing proper engagement with rack rails 212.

Further, the upper portion of 2U information handling system 202-2 includes lateral projections 214 that are wider than the lower portion of 2U information handling system 202-2. These lateral projections 214 also interfere with rack rails 212. Even if different 2U server rails 211 (not shown in FIG. 2) were used with the 2U system to address the vertical shift issues, there would still be incompatibility due to the lateral projections 214.

Embodiments of this disclosure address these difficulties. Embodiments may be implemented as a single multi-shelf system having a left rail panel and a right rail panel, designed as a larger rail feature that is capable of mounting multiple systems. For example, a 10U embodiment is capable of mounting 10 1U systems, 5 2U systems, or any combination thereof. Other sizes are also specifically contemplated, as one of ordinary skill in the art with the benefit of this disclosure will appreciate.

Components of the multi-shelf and rails according to this disclosure may be formed of any suitable material (e.g., steel, aluminum, etc.). In some embodiments, they may be stamped sheet metal. In other embodiments, they may be machined. In yet other embodiments, other production methods may be used.

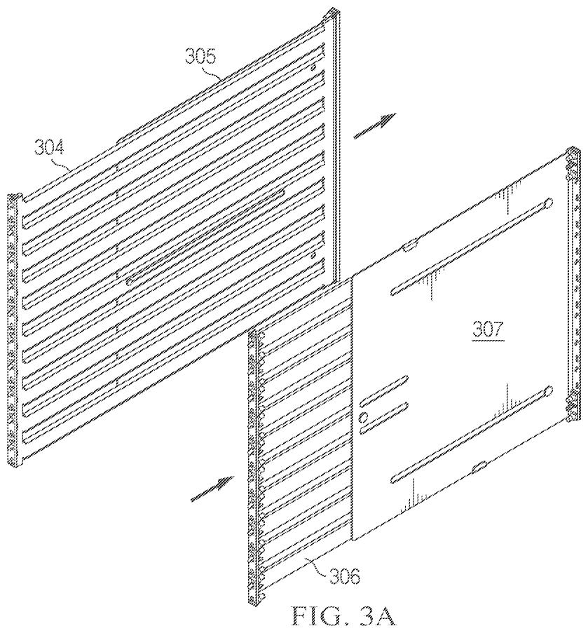

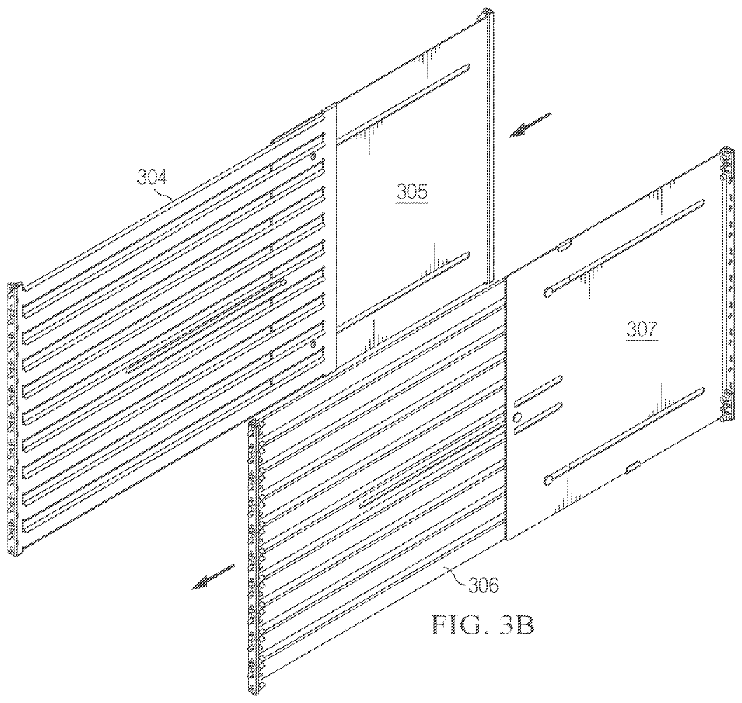

FIGS. 3A and 3B show an embodiment of a multi-shelf having a left rail panel 304 slidably coupled to a left panel 305, and a right rail panel 306 slidably coupled to a right panel 307. Left panel 305 and right panel 307 may be attached to the rearward portion of a server rack, and rail panels 304 and 306 may then be translated forward and backward as shown, to accommodate different rack depths. Further, all the mounting features of the multi-shelf may be compatible with (e.g., the same as) those of standard rails.

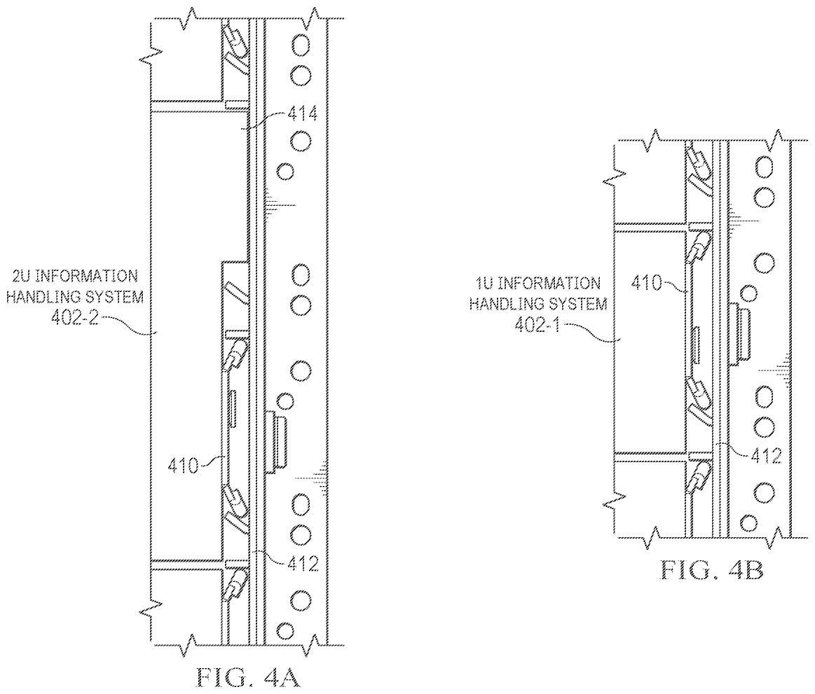

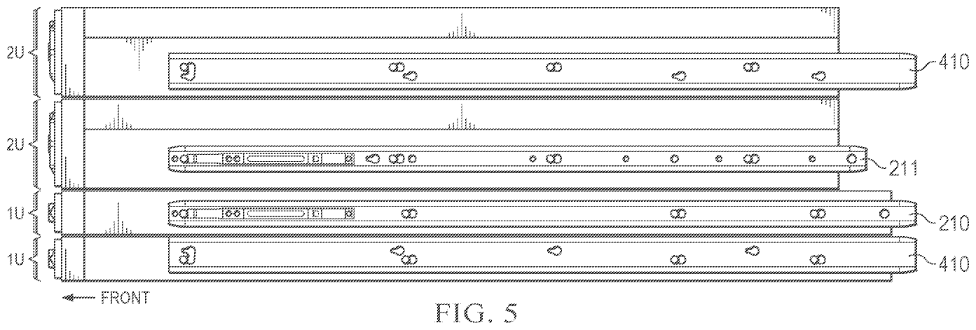

FIGS. 4A and 4B show partial views of the right panel of a multi-shelf, in accordance with embodiments of this disclosure. Rack rails 412 in this embodiment have an angled bottom portion and a horizontal top portion. This is in contrast to rack rails 212 shown in FIG. 2, which have angled top and bottom portions. The angled bottom portion in this embodiment is sufficient to support and retain server rails 410 when they are installed on information handling systems 402.

In FIG. 4A, a 2U information handling system 402-2 has been installed by mounting a server rail 410 to it and inserting the server rail 410 into rack rail 412. In FIG. 4B, a 1U information handling system 402-1 has been installed by mounting a server rail 410 to it and inserting the server rail 410 into rack rail 412.

As can be seen, the disposition of rack rails 412 provides clearance for lateral projections 414 of 2U information handling system 402-2. Further, as indicated by the circled portions in both views, the mounting locations for server rails 410 are different on the two different information handling systems, one being vertically offset from the other. As discussed in more detail below, server rails 410 have mounting holes that are operable to accommodate either mounting location, shifting up and down as necessary depending on what size of information handling system is being attached.

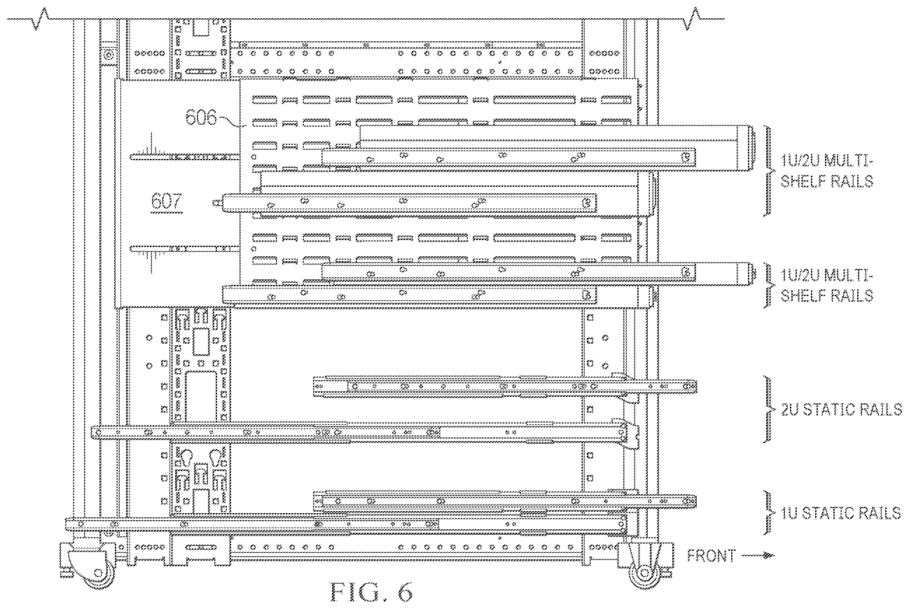

Turning now to FIG. 5, a side view of two 1U and two 2U information handling systems is shown, illustrating the contrast between the “legacy” server rails of FIG. 2 and server rails 410 of FIGS. 4A and 4B. Legacy 1U server rails 210 are shown as in FIG. 2, along with legacy 2U server rails 211. As shown, the mounting holes on server rails 410 are disposed to accommodate both 1U and 2U systems, translating up and down as needed (e.g., translating down when mounted on a 1U system and up when mounted on a 2U system).

Turning now to FIG. 6, a side view of a server rack is shown, illustrating the contrast between legacy static rails and multi-shelf rails according to this disclosure. In the bottom portion of FIG. 6, legacy 1U and 2U static server and rack rails are shown. In the top portion of FIG. 6, rail panel 606 is shown slidably coupled to panel 607. Rail panel 606 is operable to accommodate both 1U and 2U systems, and the same server rails 610 are used in both cases.

Thus embodiments of this disclosure may provide many benefits. Large-scale deployments may be significantly simplified by decreasing the number of individual rack rails that must be installed. Further, embodiments may reduce the number of distinct parts that must be produced, stocked, and shipped by allowing a single type of server rail to be used in both the 1U and the 2U case.

Although various possible advantages with respect to embodiments of this disclosure have been described, one of ordinary skill in the art with the benefit of this disclosure will understand that in any particular embodiment, not all of such advantages may be applicable. In any particular embodiment, some, all, or even none of the listed advantages may apply.

This disclosure encompasses all changes, substitutions, variations, alterations, and modifications to the exemplary embodiments herein that a person having ordinary skill in the art would comprehend. Similarly, where appropriate, the appended claims encompass all changes, substitutions, variations, alterations, and modifications to the exemplary embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

Unless otherwise specifically noted, articles depicted in the drawings are not necessarily drawn to scale. However, in some embodiments, articles depicted in the drawings may be to scale.

Further, reciting in the appended claims that a structure is “configured to” or “operable to” perform one or more tasks is expressly intended not to invoke 35 U.S.C. § 112(f) for that claim element. Accordingly, none of the claims in this application as filed are intended to be interpreted as having means-plus-function elements. Should Applicant wish to invoke § 112(f) during prosecution, Applicant will recite claim elements using the “means for [performing a function]” construct.

All examples and conditional language recited herein are intended for pedagogical objects to aid the reader in understanding the invention and the concepts contributed by the inventor to furthering the art, and are construed as being without limitation to such specifically recited examples and conditions. Although embodiments of the present inventions have been described in detail, it should be understood that various changes, substitutions, and alterations could be made hereto without departing from the spirit and scope of the disclosure.

What is claimed is:

1. A server shelf comprising:
a left rail panel coupleable to a left side of a server rack, the left rail panel including a plurality of left rack rails; and
a right rail panel coupleable to a right side of the server rack, the right rail panel including a plurality of right rack rails;
wherein each left rack rail includes a horizontal upper protrusion and an angled lower protrusion configured to receive a left server rail therebetween, and each right rack rail includes a horizontal upper protrusion and an angled lower protrusion configured to receive a right server rail therebetween;
wherein the left server rail and the right server rail are coupleable to a server of a first size and insertable into the server shelf; and
wherein the left server rail and the right server rail are coupleable to a server of a second, different size and insertable into the server shelf.

2. The server shelf of claim 1, wherein the left rail panel is slidably coupled to a left panel, and the right rail panel is slidably coupled to a right panel, the left panel and the right panel being coupleable to the server rack.

3. The server shelf of claim 1, wherein the first size is one EIA-310 unit (1U).

4. The server shelf of claim 1, wherein the second size is two EIA-310 units (2U).

5. The server shelf of claim 1, wherein the left server rail and the right server rail have a first set of mounting holes usable by the server of the first size.

6. The server shelf of claim 5, wherein the left server rail and the right server rail have a second set of mounting holes usable by the server of the second size.

7. The server shelf of claim 1, wherein the server of the second size has an upper portion that is laterally wider than a lower portion thereof.

8. A method comprising:
forming a left rail panel that is coupleable to a left side of a server rack, the left rail panel including a plurality of left rack rails; and
forming a right rail panel that is coupleable to a right side of the server rack, the right rail panel including a plurality of right rack rails;
wherein each left rack rail includes a horizontal upper protrusion and an angled lower protrusion configured to receive a left server rail therebetween, and each right rack rail includes a horizontal upper protrusion and an angled lower protrusion configured to receive a right server rail therebetween;
wherein the left server rail and the right server rail are coupleable to a server of a first size and insertable into the server shelf; and
wherein the left server rail and the right server rail are coupleable to a server of a second, different size and insertable into the server shelf.

9. The method of claim 8, wherein the left rail panel is slidably coupled to a left panel, and the right rail panel is slidably coupled to a right panel, the left panel and the right panel being coupleable to the server rack.

10. The method of claim 8, wherein the first size is one EIA-310 unit (1U).

11. The method of claim 8, wherein the second size is two EIA-310 units (2U).

12. The method of claim 8, wherein the left server rail and the right server rail have a first set of mounting holes usable by the server of the first size.

13. The method of claim 12, wherein the left server rail and the right server rail have a second set of mounting holes usable by the server of the second size.

14. The method of claim 8, wherein the server of the second size has an upper portion that is laterally wider than a lower portion thereof.
